(19) United States
(12) Patent Application Publication
(10) Pub. No.: US 2024/0194741 A1
(43) Pub. Date: Jun. 13, 2024

(54) SILICON CARBIDE SEMICONDUCTOR DEVICE AND METHOD OF FABRICATING SILICON CARBIDE SEMICONDUCTOR DEVICE

(71) Applicant: FUJI ELECTRIC CO., LTD., Kanagawa (JP)

(72) Inventor: Masakazu BABA, Matsumoto-city (JP)

(21) Appl. No.: 18/491,808

(22) Filed: Oct. 23, 2023

(30) Foreign Application Priority Data
Dec. 9, 2022 (JP) 2022-196994

(51) Int. Cl. H01L 29/16; H01L 27/092; H01L 29/06; H01L 29/66; H01L 29/78

(52) U.S. Cl. CPC H01L 29/1608; H01L 27/092; H01L 29/0623; H01L 29/66068; H01L 29/66734; H01L 29/7813

(57) ABSTRACT

Provided is a silicon carbide semiconductor device comprising: a plurality of trench portions provided on a front surface of a semiconductor substrate; a drift region of a first conductivity-type provided on the semiconductor substrate; a base region of a second conductivity type provided above the drift region; a source region of the first conductivity-type provided above the drift region and having a higher doping concentration than the drift region; a contact region of the second conductivity type provided above the drift region and having a higher doping concentration than the base region; and a second conductivity type region provided below the source region and above a lower end of the base region and having a higher doping concentration than the base region, wherein the second conductivity type region is provided to be in contact with a side wall of the plurality of trench portions.

The contents of the following patent application(s) are incorporated herein by reference: NO. 2022-196994 filed in JP on Dec. 9, 2022

### BACKGROUND

### 1. Technical Field

The present invention relates to a silicon carbide semiconductor device and a method of fabricating the silicon carbide semiconductor device.

### 2. Related Art

Patent document 1 describes a configuration in which “a third P+ type region 23 is

selectively provided near a side wall of a trench 7 and spaced apart from the side wall of the trench 7 inside a P+ type silicon carbide layer 32.”

### PRIOR ART DOCUMENTS

### Patent Documents

Patent Document 1: Japanese Patent Application Publication No. 2019-50240
Patent Document 2: Japanese Patent Application Publication No. 2021-197384

### BRIEF DESCRIPTION OF THE DRAWINGS

FIG. 1 is a view illustrating an example of an upper surface of a silicon carbide semiconductor device 100.

FIG. 2A is a view illustrating an example of a Y-Z cross section of the silicon carbide semiconductor device 100.

FIG. 2B is a view illustrating an example of a Y-Z cross section of the silicon carbide semiconductor device 100.

FIG. 2C is a view illustrating an example of an X-Z cross section of the silicon carbide semiconductor device 100.

FIG. 3 is a view illustrating a modification example of the upper surface of the silicon carbide semiconductor device 100.

FIG. 4A is a view illustrating a modification example of the Y-Z cross section of the silicon carbide semiconductor device 100.

FIG. 4B is a view illustrating a modification example of the Y-Z cross section of the silicon carbide semiconductor device 100.

FIG. 5 is a view illustrating a modification example of the upper surface of the silicon carbide semiconductor device 100.

FIG. 6 is a flowchart illustrating an example of a fabrication process of the silicon carbide semiconductor device 100.

FIG. 7 is a view illustrating an example of a fabrication process of the silicon carbide semiconductor device 100.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper”, “lower”, “front”, and “back” directions are not limited to a direction of gravity, or a direction of an attachment to a substrate or the like when a semiconductor device is mounted.

In this specification, technical matters may be described with orthogonal coordinate axes consisting of an X axis, a Y axis, and a Z axis. In this specification, a surface parallel to an upper surface of a semiconductor substrate is defined as an X-Y surface, and a depth direction of the semiconductor substrate is defined as the Z axis.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

In the present specification, in a layer or a region specified with N or P, electrons or holes are meant to be majority carriers, respectively. Also, ‘+’ and ‘−’ attached on ‘N’ and ‘P’ respectively mean that the higher doping concentration and the lower doping concentration than the layer or region to which it is not attached.

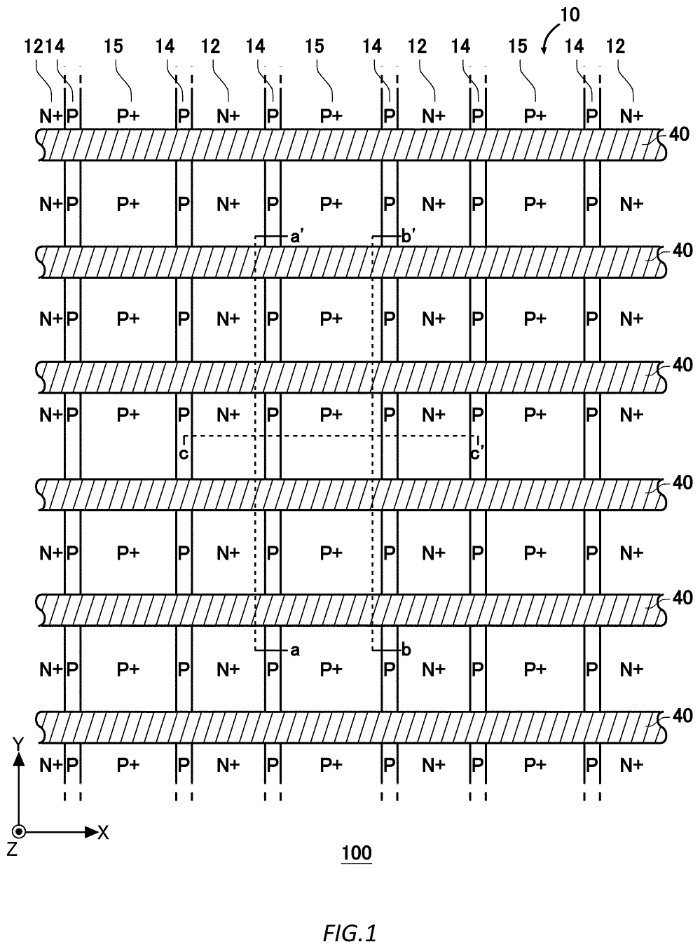

FIG. 1 is a view illustrating an example of an upper surface of a silicon carbide semiconductor device 100. The silicon carbide semiconductor device 100 may be a power semiconductor device which controls high voltage and/or high current. As an example, the silicon carbide semiconductor device 100 is a MOSFET. The silicon carbide semiconductor device 100 has a semiconductor substrate 10, and includes an active portion and a voltage-resistant structure (not shown) in the semiconductor substrate 10. The silicon carbide semiconductor device 100 of the present example includes, on a front surface 21 of the semiconductor substrate 10, a source region 12, a base region 14, a contact region 15, and a gate trench portion 40.

The semiconductor substrate 10 consists of silicon carbide. The semiconductor substrate 10 has the front surface 21. The semiconductor substrate 10 may be formed by an epitaxial deposition. As an example, the crystal structure of the semiconductor substrate 10 is 4H—SiC. In FIG. 1, an X axis may be in a [11-20] direction of the semiconductor substrate 10 consisting of silicon carbide, a Y axis may be in a [1-100] direction of the semiconductor substrate 10, and a Z axis may be in a [000-1] direction of the semiconductor substrate 10.

The active portion is provided on the semiconductor substrate 10. The active portion may be a region through which main current flows during the operation of the silicon carbide semiconductor device 100. As an example, the active portion has a Metal-Oxide-Semiconductor Field Effect Transistor (MOSFET) structure, but is not limited thereto.

The voltage-resistant structure is provided on the circumference of the active portion in the semiconductor substrate 10. The voltage-resistant structure may mitigate electric field concentration at the upper surface side of the semiconductor substrate 10. As an example, the voltage-resistant structure has a Junction Termination Extention (JTE) structure. As a modification example, the voltage-resistant structure may include, for example, a guard ring, a field plate, a RESURF (reduced surface field) and combination thereof.

A trench structure is formed on the upper surface side of the silicon carbide semiconductor device 100. Specifically, a plurality of gate trench portions 40 are formed on the front surface 21 of the semiconductor substrate 10.

The source region 12 is a region of the first conductivity type provided on the front surface 21 of the semiconductor substrate 10. The source region 12 of the present example is of an N+ type as an example. The source region 12 may be in contact with a side wall of the gate trench portions 40. The source region 12 of the present example is provided so as to extend from a side wall of one gate trench portion 40 to a side wall of another gate trench portion 40 adjacent thereto in an arrangement direction of the gate trench portions 40. The source region 12 may be also provided so as to face another source region 12 with a gate trench portion 40 sandwiched therebetween. That is, in a top view, the source region 12 may be provided in a striped pattern in the arrangement direction of the gate trench portions 40.

The source region 12 may be formed by forming a mask such as a photoresist on the front surface 21 of the semiconductor substrate 10 and performing an ion implantation into the front surface 21 of the semiconductor substrate 10. The source region 12 may be formed on an epitaxial layer of the semiconductor substrate 10. As an example, a dopant for forming the source region 12 may be phosphorus or nitrogen. The source region 12 may be formed by an ion implantation of one step, or may be formed by an ion implantation of two or more steps.

The doping concentration of the source region 12 of the present example may be higher than the doping concentration of the drift region 18 described below.

As an example, the doping concentration of the source region 12 may be 1×10¹⁸ cm⁻³ or more, and may be 1×10²¹ cm⁻³ or less.

The base region 14 is a region of a second conductivity-type provided so as to extend in the depth direction of the semiconductor substrate 10 on the front surface 21 of the semiconductor substrate 10. The base region 14 of the present example is of a P type as an example. The base region 14 is provided between the source region 12 and the contact region 15 on the front surface 21 of the semiconductor substrate 10. The base region 14 may be provided so as to extend from a side wall of one gate trench portion 40 to a side wall of another gate trench portion 40 adjacent thereto in the arrangement direction of the gate trench portions 40 on the front surface 21 of the semiconductor substrate 10.

The base region 14 may be provided by performing an epitaxial deposition of silicon carbide above the drift region 18 while doping a dopant of a P type. The dopant of the P type is aluminum atom as an example. The doping concentration of the base region 14 of the present example may be higher than the doping concentration of the drift region 18. As an example, the doping concentration of the base region 14 may be 2×10¹⁶ cm⁻³ or more, and may be 2×10¹⁷ cm⁻³ or less.

In an example, the source region 12 and the contact region 15 may be separated by providing the base region 14 between the source region 12 and the contact region 15. A width W14X of the base region 14 on the front surface 21 of the semiconductor substrate 10 in an extending direction of the gate trench portions 40 may be 0.2 μm or more, and may be 0.5 μm or less.

The contact region 15 is a region of the second conductivity type provided on the front surface 21 of the semiconductor substrate 10. The contact region 15 of the present example is of a P+ type as an example. The contact region 15 may be provided so as to extend from a side wall of one gate trench portion 40 to a side wall of another gate trench portion 40 adjacent thereto in the arrangement direction of the gate trench portions 40. The contact region 15 may be also provided so as to face another contact region 15 with a gate trench portion 40 sandwiched therebetween. That is, in a top view, the contact region 15 may be provided in a striped pattern in the arrangement direction of the gate trench portions 40.

The contact region 15 may be formed by forming a mask such as a photoresist on the front surface 21 of the semiconductor substrate 10 and performing an ion implantation into the front surface 21 of the semiconductor substrate 10. The contact region 15 may be formed on an epitaxial layer of the semiconductor substrate 10. A dopant for forming the contact region 15 may be aluminum or boron. The contact region 15 may be formed by an ion implantation of one step, or may be formed by an ion implantation of two or more steps.

The doping concentration of the contact region 15 of the present example may be higher than the doping concentration of the drift region 18 described below, and may be higher than the doping concentration of the base region 14. As an example, the doping concentration of the contact region 15 may be 1×10¹⁹ cm⁻³ or more, and may be 1×10²⁰ cm⁻³ or less.

A width of the contact region 15, in the extending direction of the gate trench portions 40 on the front surface 21 of the semiconductor substrate 10, may be greater than a width of the source region 12, or may be the same as that. In addition, the width of the source region 12 may be greater than the width of the base region 14.

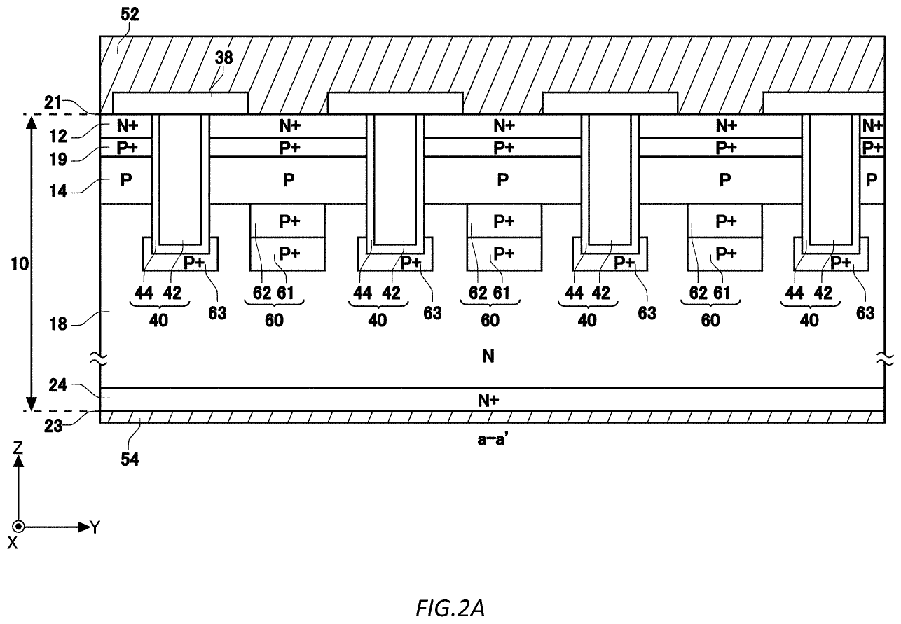

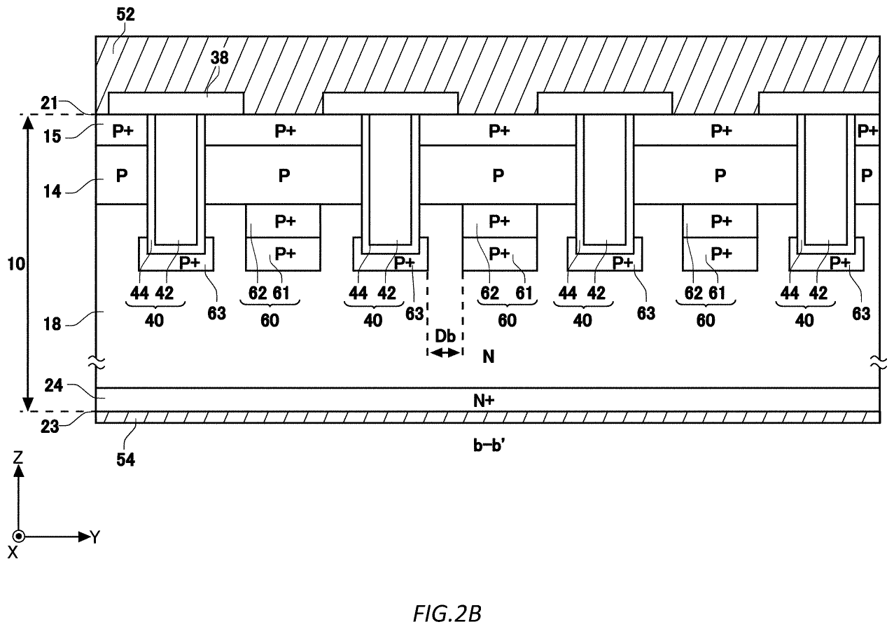

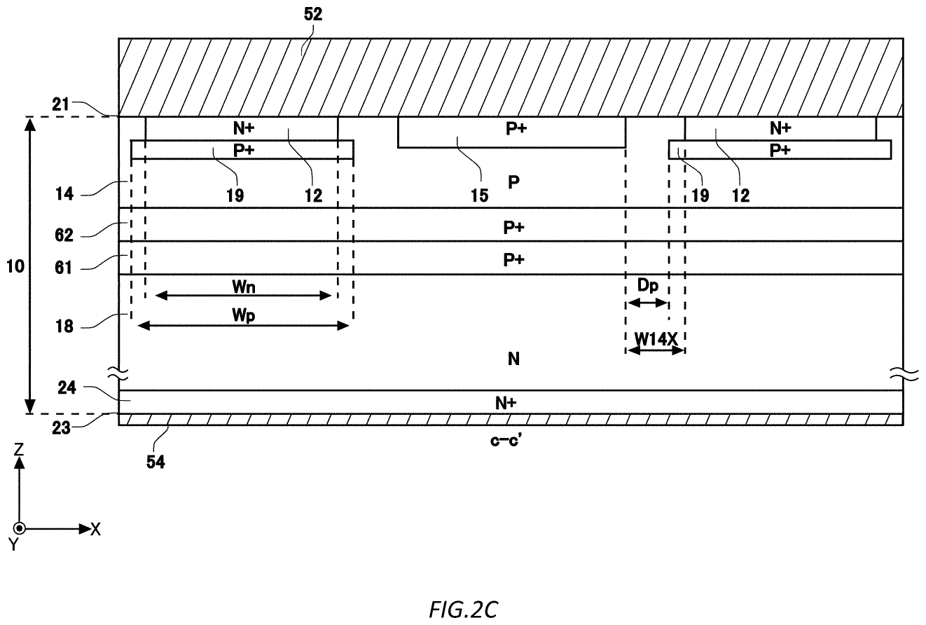

FIG. 2A is a view illustrating an example of a Y-Z cross section of the silicon carbide semiconductor device 100 in an a-a′ line in FIG. 1. FIG. 2A is a Y-Z cross-sectional view of the region of the silicon carbide semiconductor device 100 in which the source region 12 is provided in a top view. The silicon carbide semiconductor device 100 of the present example includes a source region 12, a base region 14, a drift region 18, a second conductivity type region 19, a buffer region 24, a dielectric film 38, a gate trench portion 40, a source electrode 52, a drain electrode 54, a body region 60, and a trench bottom region 63.

The drift region 18 is a region of the first conductivity type which is provided in the semiconductor substrate 10. The drift region 18 of the present example is of an N type as an example. The drift region 18 may be provided by performing an epitaxial deposition of silicon carbide while doping a dopant of an N type. The dopant of the N type is nitrogen atom as an example. The doping concentration of the drift region 18 of the present example may be lower than the doping concentration of the buffer region 24.

The buffer region 24 is a region of the first conductivity type which is provided on the back surface 23 of the semiconductor substrate 10. The buffer region 24 is provided below the drift region 18. The buffer region 24 of the present example is of an N+ type as an example. The buffer region 24 may be a silicon carbide substrate consisting of silicon carbide of an N+ type.

The second conductivity type region 19 is a region of the second conductivity type provided above the lower end of the base region 14 below the source region 12. The second conductivity type region 19 of the present example is of a P+ type as an example. The second conductivity type region 19 is provided to be in contact with the side walls of the gate trench portions 40. The second conductivity type region 19 may be provided so as to extend from a side wall of one gate trench portion 40 to a side wall of another gate trench portion 40 adjacent thereto in the arrangement direction of the gate trench portions 40. The upper end of the second conductivity type region 19 may be or may not be in contact with the lower end of the source region 12.

The doping concentration of the second conductivity type region 19 may be higher than the doping concentration of the base region 14, and may be lower than or equal to the doping concentration of the contact region 15. As an example, the doping concentration of the second conductivity type region 19 may be 1×10¹⁸ cm⁻³ or more, and may be 1×10²⁰ cm⁻³ or less.

Since the doping concentration of the second conductivity type region 19 is sufficiently higher than that of the base region 14, the second conductivity type region 19 is a region where no channel formation is occurred during the operation of the MOSFET. That is, in the second conductivity type region 19, no inversion region is formed during the operation of the MOSFET. By providing the second conductivity type region 19 only below the source region 12, channel current flowing into from the immediately below the second conductivity type region 19 during the operation of the MOSFET is inhibited, and only current from other than the immediately below it flows. In this way, the short circuit withstand capability of the silicon carbide semiconductor device 100 can be improved. In addition, the channel lengths become uniform, and the variations in the characteristics of the silicon carbide semiconductor device 100 are suppressed.

The second conductivity type region 19 may be formed by forming a mask such as a photoresist on the front surface 21 of the semiconductor substrate 10 and performing an ion implantation into the front surface 21 of the semiconductor substrate 10. The second conductivity type region 19 may be formed on an epitaxial layer of the semiconductor substrate 10. As an example, the implanted ion may be aluminum ion. The second conductivity type region 19 may be formed by an ion implantation of one step, or may be formed by an ion implantation of two or more steps.

The thickness of the second conductivity type region 19 in the depth direction of the semiconductor substrate 10 may be lower than the thickness of the source region 12 in the depth direction of the semiconductor substrate 10. As an example, the thickness of the second conductivity type region 19 may be 0.05 μm or more, and may be 0.2 μm or less.

The gate trench portion 40 is provided on the front surface 21 of the semiconductor substrate 10. The gate trench portion 40 may be provided to penetrate the base region 14 to reach the drift region 18. A configuration in which the gate trench portion 40 penetrates the base region 14 is not limited to a configuration which is fabricated by forming the base region 14 and then forming the gate trench portion 40. A configuration in which the base region 14 is formed on the side wall of the gate trench portion 40 after the gate trench portion 40 is formed is also included in the configuration in which the gate trench portion 40 penetrates the base region 14. The bottom portion of the gate trench portion 40 may be covered by a trench bottom region 63 described below.

The gate trench portion 40 includes a gate dielectric film 44 and a gate conductive portion 42. The gate dielectric film 44 is formed to cover an inner wall of the gate trench portion 40. The gate dielectric film 44 may be formed by oxidizing the semiconductor of the inner wall of the gate trench portion 40.

The gate conductive portion 42 is formed inside the gate trench portion 40 in a more inner side than the gate dielectric film 44. The gate dielectric film 44 insulates the gate conductive portion 42 and the semiconductor substrate 10. The gate conductive portion 42 is formed of a conductive material for example, a polysilicon (a doped polysilicon) added with the N type impurity such as phosphorus (P) or the P type impurity such as boron (B) at high impurity concentration, or a high-melting-point metal such as titanium (Ti) or tungsten (W). The gate trench portion 40 is covered by the dielectric film 38 on the front surface 21 of the semiconductor substrate 10.

The source electrode 52 is set to a source potential, and is provided above the semiconductor substrate 10 with the dielectric film 38 therebetween. The source electrode 52 is formed of a material containing metal. The source electrode 52 may include a barrier metal. At least a part of the region of the source electrode 52 may be formed of metal such as aluminum (Al), or a metal alloy such as an aluminum-silicon alloy (AlSi), an aluminum-silicon-copper alloy (AlSiCu).

The drain electrode 54 is formed on the back surface 23 of the semiconductor substrate 10. The drain electrode 54 is formed of a conductive material such as metal. For the drain electrode 54, a single-layer film consisting of, e.g., gold (Au), or a metal film obtained by stacking titanium (Ti), nickel (Ni), and Au in this order is usable, and further metal film such as molybdenum (Mo), tungsten (W) may be stacked below the lowermost layer thereof. In addition, a silicide layer consisting of nickel silicide (NiSix) etc., between the back surface 23 of the semiconductor substrate 10 and the drain electrode 54 may be provided.

The trench bottom region 63 is a region of the second conductivity type provided at the lower end of the gate trench portion 40 so as to cover the bottom and a part of the side surface of the gate trench portion 40. The trench bottom region 63 of the present example is of a P+ type as an example. By providing the trench bottom region 63, the breakdown voltage of the silicon carbide semiconductor device 100 can be improved.

The body region 60 is a region of the second conductivity type provided to be in contact with the lower end of the base region 14 between the adjacent gate trench portions 40. The body region 60 of the present example is of a P+ type as an example. The body region 60 of the present example includes a first body region 61 and a second body region 62. The body region may be formed by way of an ion implantation of two steps into the front surface 21 of the semiconductor substrate 10, or may be formed by way of an ion implantation of one step.

The first body region 61 is provided below the lower end of the base region 14. The first body region 61 may be formed concurrently with forming the trench bottom region 63. In the depth direction of the semiconductor substrate 10, the first body region 61 may be formed at the same depth as the trench bottom region 63.

The second body region 62 is provided between the base region 14 and the first body region 61. The second body region 62 is provided to be in contact with the base region 14 and the first body region 61.

When an avalanche breakdown is occurred in the silicon carbide semiconductor device 100, an avalanche current higher than an operating current may flow into the gate trench portion 40. In the present example, by providing the body region 60, the avalanche current can flow through the body region 60 to the front surface 21, and the flow of the avalanche current to the gate trench portion 40 can be suppressed.

FIG. 2B is a view illustrating an example of a Y-Z cross section of the silicon carbide semiconductor device 100 in a b-b′ line in FIG. 1. FIG. 2B is a Y-Z cross-sectional view of the region of the silicon carbide semiconductor device 100 in which the contact region 15 is provided in a top view. FIG. 2B will be used to describe the difference from FIG. 2A.

In FIG. 2B, the contact region 15 is formed on the entire front surface 21 of the semiconductor substrate 10. The contact region 15 may be provided so as to extend from a side wall of one gate trench portion 40 to a side wall of another gate trench portion 40 adjacent thereto in the arrangement direction of the gate trench portions 40.

The second conductivity type region 19 may not be provided below the contact region 15. Due to the fact that the second conductivity type region 19 is not provided below the contact region 15, a current path through which main current flows is ensured.

A predetermined distance Db is provided between the first body region 61 and the trench bottom region 63 in the arrangement direction of the gate trench portions 40. Db may be 0.2 μm or more, and may be 0.6 μm or less.

FIG. 2C is a view illustrating an example of an X-Z cross section of the silicon carbide semiconductor device 100 in a c-c′ line in FIG. 1. FIG. 2C is an X-Z cross section view of the region of the silicon carbide semiconductor device 100 through the center of the adjacent gate trench portions 40.

The second conductivity type region 19 of the present example is provided only below the source region 12. In addition, A width Wp of the second conductivity type region 19 may be the same as a width Wn of the source region 12 or may be greater than the width Wn of the source region 12 in the extending direction of the gate trench portions 40 (the X axis direction of FIG. 2C).

If the second conductivity type region 19 is not provided below the source region 12, a channel current during the operation of the MOSFET flows into from all directions below the source region 12. If so, a current flowing into from the immediately below the source region 12 and a current flowing into from other than the immediately below may vary in length of channels, and cause variations in characteristics of the silicon carbide semiconductor device 100.

In the present example, due to the fact that the second conductivity type region 19 is provided below the source region 12, the current during the operation of the MOSFET flowing into from below the source region 12 can be suppressed. In this way, the channel lengths of the current paths become uniform, and the variations in the characteristics of the silicon carbide semiconductor device 100 are suppressed.

A predetermined distance Dp is provided between the contact region 15 and the second conductivity type region 19 in the extending direction of the gate trench portions 40. That is, in the extending direction of the gate trench portions 40, by providing the base region 14 between the contact region 15 and the second conductivity type region 19, the contact region 15 and the second conductivity type region 19 are separated.

The distance Dp between the contact region 15 and the second conductivity type region 19 in the extending direction of the gate trench portions 40 is greater than the distance Db between the first body region 61 and the trench bottom region 63 in the arrangement direction of the gate trench portions 40. By having Dp greater than Db, the heat generation near a surface of the silicon carbide semiconductor device 100 can be suppressed, and the operating stability can be increased.

Due to the fact that the contact region 15 and the second conductivity type region 19 are spaced apart by the predetermined distance Dp, the heat generation near a surface of the silicon carbide semiconductor device 100 can be suppressed. The predetermined distance Dp may be 0.2 μm or more, and may be 0.45 μm or less.

As mentioned above, the active portion may have the trench-type MOSFET structure. For each component of the active portion, examples of the fabrication method thereof have been described, but the fabrication method of the active portion is not limited the above method. The active portion can be fabricated by common methods used by one of ordinary skill in the art.

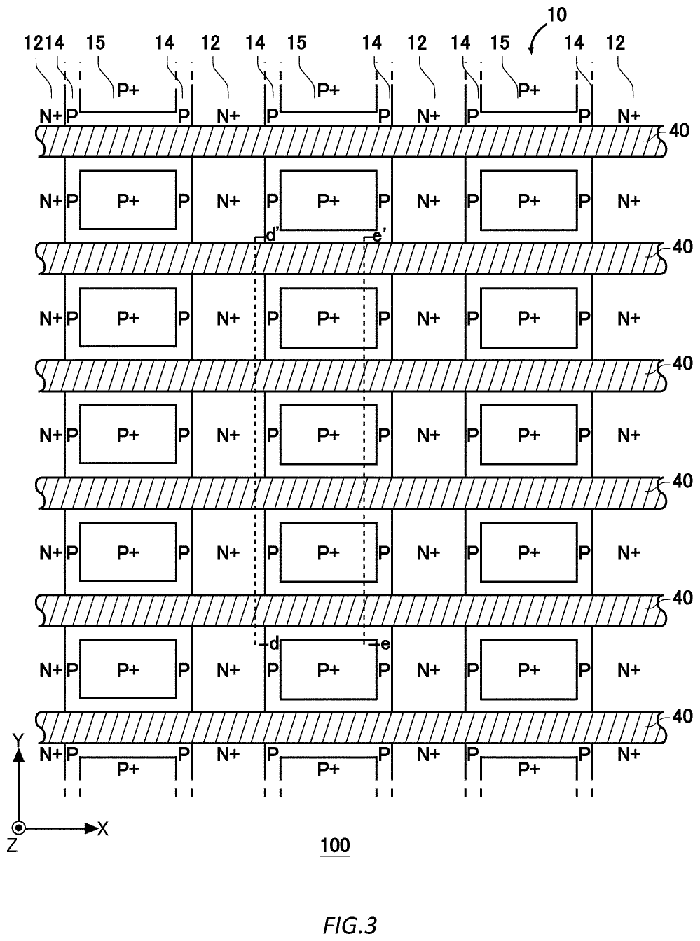

FIG. 3 is a view illustrating a modification example of an upper surface of the silicon carbide semiconductor device 100. The example embodiment of FIG. 3 differs from the example embodiment of FIG. 1 in that the base region 14 is provided between the gate trench portion 40 and the contact region 15 on the front surface 21 of the semiconductor substrate 10. That is, the contact region 15 is separate from the gate trench portion 40 on the front surface 21 of the semiconductor substrate 10. By providing the base region 14 between the gate trench portion 40 and the contact region 15, saturated current can be decreased, and the short circuit withstand capability of the silicon carbide semiconductor device 100 can be improved.

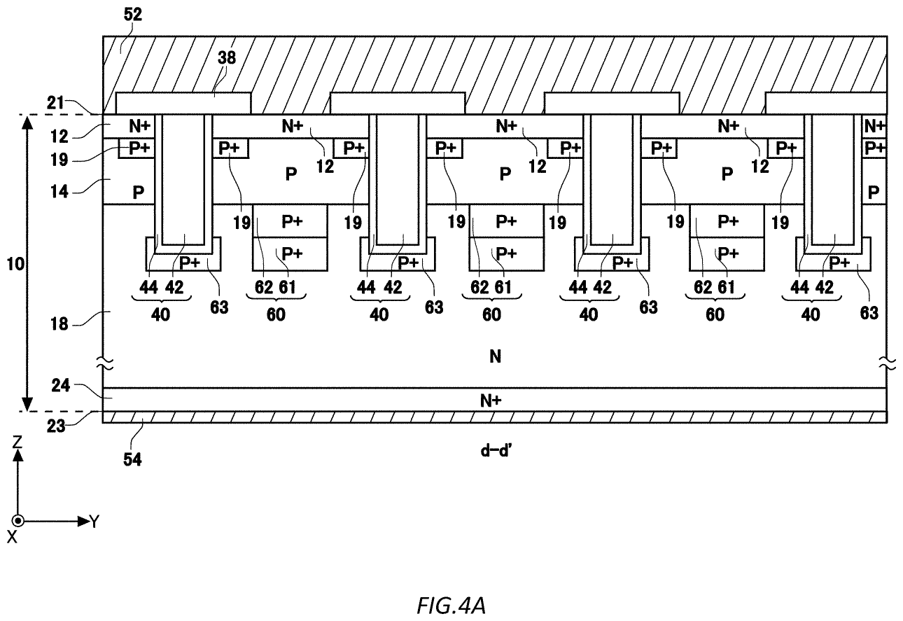

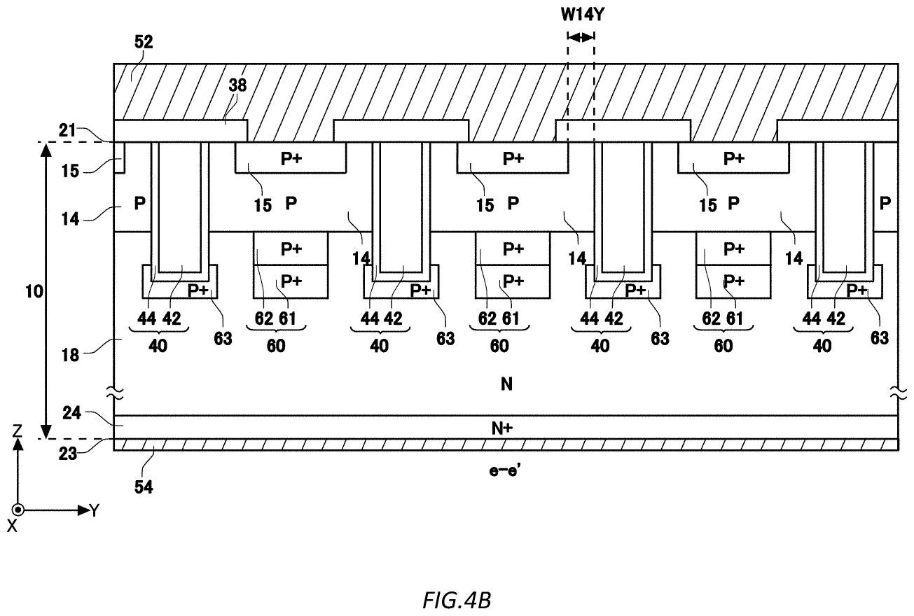

FIG. 4A is a view illustrating a modification example of a Y-Z cross section of the silicon carbide semiconductor device 100 in a d-d′ line in FIG. 3. The example embodiment shown in FIG. 4A differs from the example embodiment of FIG. 2A in that the second conductivity type region 19 terminates so as not to extend from a side wall of one gate trench portion 40 to a side wall of another gate trench portion 40 adjacent thereto in the arrangement direction of the gate trench portions 40.

In the present example, due to the fact that the second conductivity type region 19 is provided below the source region 12, the channel lengths of the current paths become uniform, and the variations in the characteristics of the silicon carbide semiconductor device 100 are suppressed. That is, the second conductivity type region 19 may not be provided the entire surface below the source region 12 as long as it is provided near the side wall of the gate trench portion 40 which will become a channel.

FIG. 4B is a view illustrating a modification example of a Y-Z cross section of the silicon carbide semiconductor device 100 in an e-e′ line in FIG. 3. The example embodiment shown in FIG. 4B differs from the example embodiment of FIG. 2B in that the base region 14 is provided between the contact region 15 and the gate trench portion 40.

The base region 14 of a predetermined width W14Y may be provided between the gate trench portion 40 and the contact region 15. The predetermined width W14Y may be greater than a width W14X between the contact region 15 and the source region 12 in the extending direction of the gate trench portions 40, or may be the same as W14X. The width W14Y of the base region 14 in the arrangement direction of the gate trench portions 40 may be 0.1 μm or more, and may be 0.5 μm or less.

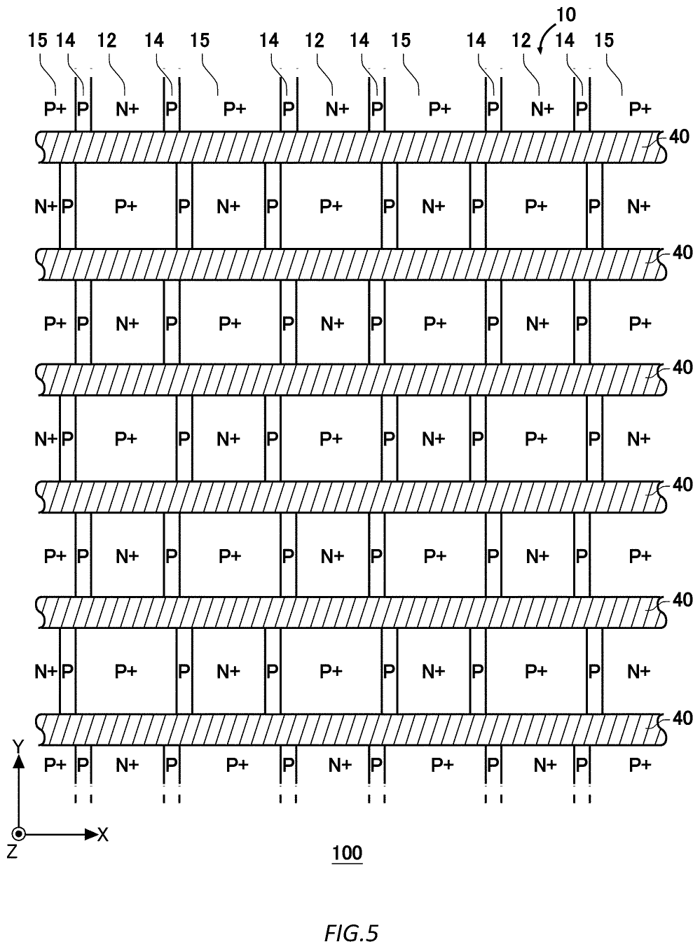

FIG. 5 is a view illustrating a modification example of an upper surface of the silicon carbide semiconductor device 100. The example embodiment of FIG. 5 differs from the example embodiment of FIG. 1 in that the configuration is such that the source region 12 faces the contact region 15 with the gate trench portion 40 therebetween, and the contact region 15 faces the source region 12 with the gate trench portion 40 therebetween. As can be seen in FIG. 5, the contact region 15 and the source region 12 may be provided in a staggered structure.

Even in the case the contact region 15 and the source region 12 are provided in the staggered structure as in FIG. 5, the source region 12 is provided so as to extend from a side wall of one gate trench portion 40 to a side wall of another gate trench portion 40 adjacent thereto in the arrangement direction of the gate trench portions 40 on the front surface 21 of the semiconductor substrate 10.

The contact region 15 may be provided so as to extend from a side wall of one gate trench portion 40 to a side wall of another gate trench portion 40 adjacent thereto in the arrangement direction of the gate trench portions 40 on the front surface 21 of the semiconductor substrate 10. In this way, the short circuit withstand capability of the silicon carbide semiconductor device 100 can be improved.

The base region 14 may be provided between the contact region 15 and the gate trench portion 40 in the arrangement direction of the gate trench portions 40. In this way, the short circuit withstand capability of the silicon carbide semiconductor device 100 can be improved.

Even in the case the contact region 15 and the source region 12 are provided in the staggered structure, the second conductivity type region 19 is provided in the partial or entire region below the source region 12. In this way, the channel lengths become uniform, and the variations in the characteristics of the silicon carbide semiconductor device 100 can be suppressed.

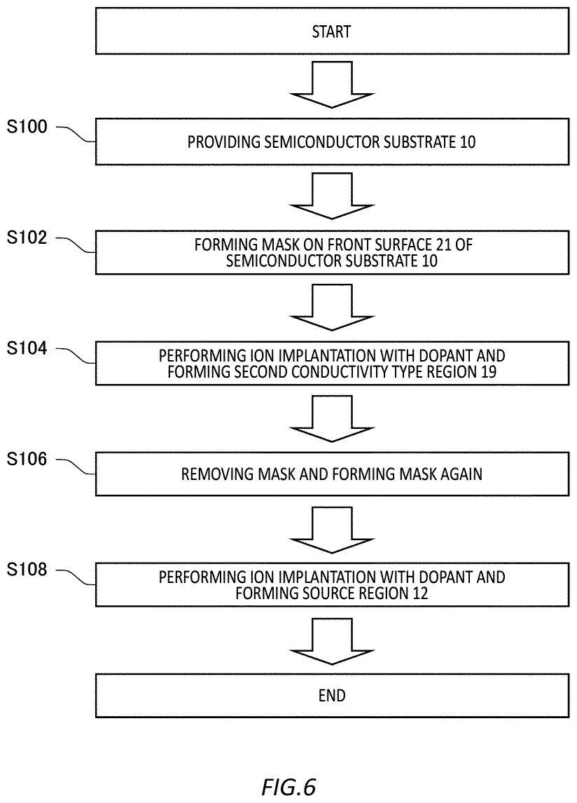

FIG. 6 is a flowchart illustrating an example of a fabrication process of the silicon carbide semiconductor device 100. The present example illustrates an example of a flowchart of a fabrication process of the silicon carbide semiconductor device 100, but is not limited thereto. FIG. 6 will be used to describe in detail for the steps of forming a source region 12 and a second conductivity type region 19.

In Step S100, a semiconductor substrate 10 consisting of silicon carbide including a buffer region 24, a drift region 18, a base region 14, a first body region 61, a second body region 62, and a trench bottom region 63, is provided. The steps of forming these regions into the semiconductor substrate 10 consisting of silicon carbide will be not described in detail herein, because the regions can be formed by common methods used by one of ordinary skill in the art.

In Step S102, a mask on a front surface 21 of the semiconductor substrate 10 is formed. The mask may be any mask such as a photoresist.

In Step S104, an ion implantation is performed with a dopant into the front surface 21 of the semiconductor substrate 10. The dopant with which the ion implantation is performed in Step S104 may be aluminum, or may be boron. By performing the ion implantation with aluminum, a second conductivity type region 19 may be formed. The ion implantation in Step S104 may be performed in one step, or may be performed in multiple steps of two or more steps. In an example, the energy for the ion implantation in Step S104 may be 0.5 MeV or more, and may be 2.0 MeV or less.

The second conductivity type region 19 may be formed to be in contact with any side wall of the gate trench portions 40 provided on the semiconductor substrate 10. The formation of the gate trench portion 40 may be performed after forming the second conductivity type region 19, or may be performed before forming the second conductivity type region 19.

In Step S106, the mask formed in Step S102 is removed, and a mask is formed again on the front surface 21 of the semiconductor substrate 10. Note that Step S106 may be omitted. If Step S106 is omitted, a width Wn of the source region 12 formed in Step S108 described below in the extending direction of the gate trench portions 40 and a width Wp of the second conductivity type region 19 in the extending direction of the gate trench portions 40 will be the same.

In Step S108, an ion implantation is performed with a dopant into the front surface 21 of the semiconductor substrate 10. The dopant with which the ion implantation is performed in Step S104 may be phosphorus, or may be nitrogen atom. By performing the ion implantation with phosphorus, a source region 12 may be formed. The ion implantation in Step S108 may be performed in one step, or may be performed in multiple steps of two or more steps.

The energy for the ion implantation in Step S108 may be smaller than the energy for the ion implantation in Step S104. In an example, the energy for the ion implantation in Step S108 may be 70 keV or more, and may be 300 keV or less. In this way, the source region 12 can be formed on the side of the front surface 21 with respect to the second conductivity type region 19.

The order of Step S104 and Step S108 may be inverted. That is, as an example, the order of performing an ion implantation with aluminum to form the second conductivity type region 19 first and then performing an ion implantation with phosphorus to form the source region 12 has been described, although the order of forming the source region 12 first and then forming the second conductivity type region 19 may be also possible.

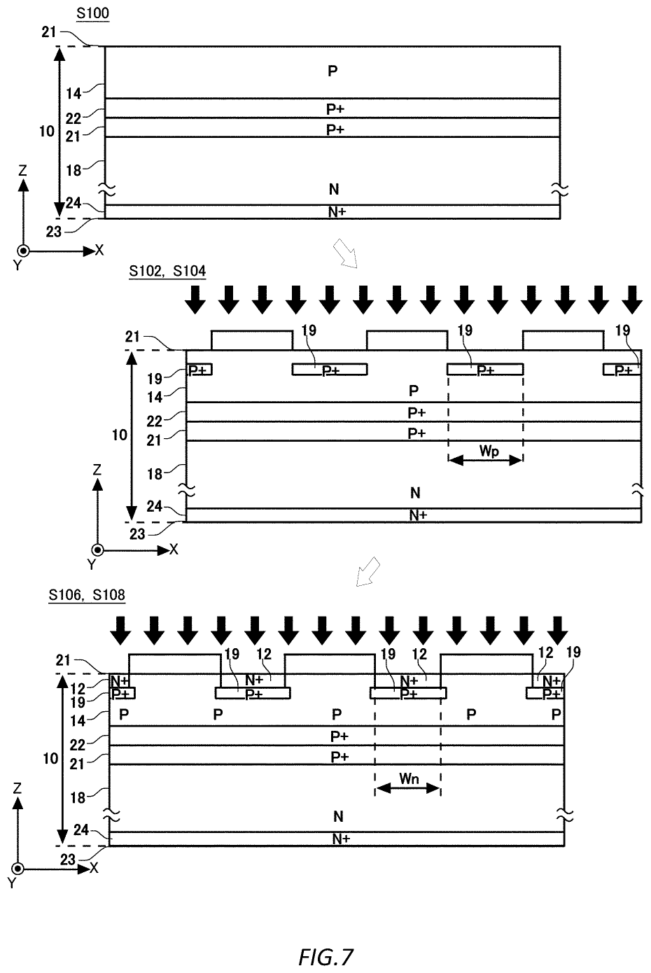

FIG. 7 is a view illustrating an example of a fabrication process of the silicon carbide semiconductor device 100. FIG. 7 is a view illustrating an X-Z cross section of the semiconductor substrate 10 in each step of FIG. 6. In a cross section illustrating Step S100, a cross section view of a cross section through the first body region 61 and the second body region 62 is illustrated, and the trench bottom region 63 is not shown.

After a mask is formed on the front surface 21 of the semiconductor substrate 10 in Step S102, the second conductivity type region 19 is formed by an ion implantation in Step S104. The second conductivity type region 19 is formed inside the base region 14 and above the lower end of the base region 14.

In Step S106, the mask formed in Step S102 is removed, and a new mask is formed. Subsequently, a source region 12 is formed by an ion implantation in Step S108.

The width of the mask formed in Step S106 in the extending direction of the gate trench portions 40 is greater than the mask formed in Step S102 in the extending direction of the gate trench portions 40. In this way, the width Wn of the source region 12 in the extending direction of the gate trench portions 40 can be smaller than the width Wp of the second conductivity type region 19 in the extending direction of the gate trench portions 40.

In addition, Step S106 can be omitted. If Step S106 is omitted, the width Wn of the source region 12 in the extending direction of the gate trench portions 40 and the width Wp of the second conductivity type region 19 in the extending direction of the gate trench portions 40 will be the same since the ion implantation in Step S104 and the ion implantation in Step S108 are performed with the same mask.

While the present invention has been described by way of the embodiments, the technical scope of the present invention is not limited to the above described embodiments. It is apparent to persons skilled in the art that various alterations or improvements can be made to the above described embodiments. It is also apparent from the description of the claims that the embodiments to which such alterations or improvements are made can be included in the technical scope of the present invention.

The operations, procedures, steps, and stages of each process performed by a device, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10: semiconductor substrate;
12: source region;
14: base region;
15; contact region;
18: drift region;
19: second conductivity type region;
21: front surface;
23: back surface;
24: buffer region;
38: dielectric film;
40: gate trench portion;
42: gate conductive portion;
44: gate dielectric film;
52: source electrode;
54: drain electrode;
60: body region;
61: first body region;
62: second body region;
63: trench bottom region;
100: silicon carbide semiconductor device.

What is claimed is:

1. A silicon carbide semiconductor device comprising:
a plurality of trench portions provided on a front surface of a semiconductor substrate;
a drift region of a first conductivity-type provided on the semiconductor substrate;
a base region of a second conductivity type provided above the drift region;
a source region of a first conductivity-type provided above the drift region and having a higher doping concentration than the drift region;
a contact region of a second conductivity type provided above the drift region and having a higher doping concentration than the base region; and
a second conductivity type region provided below the source region and above a lower end of the base region and having a higher doping concentration than the base region, wherein
the second conductivity type region is provided to be in contact with a side wall of any trench portion of the plurality of trench portions.

2. The silicon carbide semiconductor device according to claim 1, wherein
a doping concentration of the second conductivity type region is greater than a doping concentration of the base region and is lower than or equal to the doping concentration of the contact region.

3. The silicon carbide semiconductor device according to claim 1, wherein a doping concentration of the second conductivity type region is 1×10¹⁸ cm⁻³ or more and 1×10²⁰ cm⁻³ or less.

4. The silicon carbide semiconductor device according to claim 1, wherein
the source region is provided so as to extend from a side wall of one trench portion of the plurality of trench portions to a side wall of another trench portion adjacent thereto in an arrangement direction of the plurality of trench portions.

5. The silicon carbide semiconductor device according to claim 1, wherein
a width of the second conductivity type region in an extending direction of the plurality of trench portions is greater than a width of the source region in the extending direction of the plurality of trench portions.

6. The silicon carbide semiconductor device according to claim 1, wherein
the base region is provided between the source region and the contact region on a front surface of the semiconductor substrate, and
the source region and the contact region are separated by the base region therebetween on the front surface of the semiconductor substrate.

7. The silicon carbide semiconductor device according to claim 1, wherein
a width of the base region between the source region and the contact region in an extending direction of the plurality of trench portions is 0.2 μm or more and 0.5 μm or less.

8. The silicon carbide semiconductor device according to claim 1, comprising:
a body region of the second conductivity type provided to be in contact with a lower end of the base region between the plurality of trench portions adjacent to each other.

9. The silicon carbide semiconductor device according to claim 8, wherein
the body region comprises a first body region and a second body region provided above the first body region,
an upper end of the second body region is in contact with the lower end of the base region, and
an upper end of the first body region is in contact with a lower end of the second body region.

10. The silicon carbide semiconductor device according to claim 1, wherein
the second conductivity type region and the contact region are separated by the base region therebetween.

11. The silicon carbide semiconductor device according to claim 9, comprising:
a trench bottom region of a second conductivity type provided on a lower end of the plurality of trench portions and having a higher doping concentration than the base region.

12. The silicon carbide semiconductor device according to claim 11, wherein
a distance between the contact region and the second conductivity type region in an extending direction of the trench portions is greater than a distance between the first body region and the trench bottom region in an arrangement direction of the trench portions.

13. The silicon carbide semiconductor device according to claim 1, wherein
a thickness of the second conductivity type region in a depth direction of the semiconductor substrate is 0.05 μm or more and 0.2 μm or less.

14. The silicon carbide semiconductor device according to claim 1, wherein
the second conductivity type region is provided so as to extend from a side wall of one trench portion to a side wall of another trench portion adjacent thereto in an arrangement direction of the plurality of trench portions.

15. The silicon carbide semiconductor device according to claim 2, wherein
the second conductivity type region is provided so as to extend from a side wall of one trench portion to a side wall of another trench portion adjacent thereto in an arrangement direction of the plurality of trench portions.

16. The silicon carbide semiconductor device according to claim 1, wherein
the second conductivity type region terminates so as not to extend from a side wall of one trench portion to a side wall of another trench portion adjacent thereto in an arrangement direction of the plurality of trench portions.

17. The silicon carbide semiconductor device according to claim 2, wherein
the second conductivity type region terminates so as not to extend from a side wall of one trench portion to a side wall of another trench portion adjacent thereto in an arrangement direction of the plurality of trench portions.

18. The silicon carbide semiconductor device according to claim 1, wherein
the source region faces another source region with the trench portion sandwiched therebetween, and the contact region faces another contact region with the trench portion sandwiched therebetween.

19. The silicon carbide semiconductor device according to claim 1, wherein
the source region faces the contact region with the trench portion sandwiched therebetween, and the contact region faces the source region with the trench portion sandwiched therebetween.

20. A method for fabricating a silicon carbide semiconductor device, comprising:
forming a mask on a front surface of a semiconductor substrate comprising a plurality of trench portions;
implanting a dopant into a front surface of the semiconductor substrate with the mask to form a second conductivity type region of a second conductivity type so as to be in contact with a side wall of any trench portion of the plurality of trench portions; and
implanting a dopant into a front surface of the semiconductor substrate with the mask to form a source region of a first conductivity type.
